(19) United States
(12) Patent Application Publication
(10) Pub. No.: US 2021/0096679 A1
(43) Pub. Date: Apr. 1, 2021

(54) TOUCH DISPLAY APPARATUS

(71) Applicant: Raydium Semiconductor Corporation, Hsinchu (TW)

(72) Inventors: CHEN-WEI YANG, Hsinchu City (TW); CHENG-NAN LIN, Taipei City (TW)

(21) Appl. No.: 17/027,864

(22) Filed: Sep. 22, 2020

Related U.S. Application Data
(60) Provisional application No. 62/908,659, filed on Oct. 1, 2019.

(51) Int. Cl. G06F 3/041; G06F 3/044; G09G 3/3208

(52) U.S. Cl. CPC G06F 3/0412; G09G 3/3208; G06F 3/044; G06F 3/04164

(57) ABSTRACT

A touch display apparatus is disclosed. The touch display apparatus includes a touch display panel, a chip on film (COF) layer and a driving circuit. The touch display panel includes a display module and a touch sensor. The touch sensor is disposed on the display module. The COF layer includes a connecting portion and an extending portion connected to each other. The connecting portion is coupled to the display module and the extending portion is coupled to the touch sensor. The driving circuit is disposed on the COF layer. The driving circuit transmits touch signals with the touch sensor through the COF layer and its extending portion.

### BACKGROUND OF THE INVENTION

### 1. Field of the Invention

The invention relates to display apparatus; in particular, to a touch display apparatus.

### 2. Description of the Prior Art

In the prior art, when an on-cell touch display panel applied to a wearable touch display apparatus is combined with a touch and display driver integrated with a chip on film (COF) package (in the case of touch and display driver integration (TDDI) integrated circuit, the touch sensor contact of the on-cell touch display panel is located on the upper glass, and the COF package is used for the TDDI integrated circuit is attached to the bottom glass of the display module. Therefore, the two need to be coupled through a flexible printed circuit (FPC) for touch, so that the TDDI integrated circuit and the touch sensor can be connected to each other and they can transmit touch signals.

At present, the commonly used methods can be divided into two types, based on that the FPC for touch and the TDDI integrated circuits using COF package are coupled at the same side or different sides, described as follows:

(1) As shown in FIG. 1, in the on-cell touch display panel 1A, the touch sensor TS disposed on the encapsulation layer ENC is coupled to the flexible printed circuit board FPCT for touch. The flexible printed circuit board FPCT is on the same side as the TDDI integrated circuit on the COF. Because the chip on film layer COF may overlap with the flexible printed circuit board FPCT for touch, and the two sides of the flexible printed circuit board FPCT for touch need to be attached to the encapsulation layer ENC and the main flexible printed circuit board FPCM respectively; therefore, when the flexible printed circuit board FPCT for touch takes into consideration the curvature when it is bent to the back, the required length is relatively long, which makes the alignment difficult and increases the difficulty of bonding, which affects the bonding yield. In addition, as shown in FIG. 3, the traces of the touch sensor TS need to pass through the flexible printed circuit board FPCT for touch, the main flexible printed circuit board FPCM and the chip on film layer COF in order to be coupled to the TDDI integrated circuit with the display driver makes the trace length too long, which is likely to cause signal attenuation and noise interference, which needs to be overcome urgently. Furthermore, considering the pitch limitation of the flexible printed circuit board FPCT for touch, when the on-cell touch display panel 1A is circular, the width required for the touch bonding area is relatively wide (for example, as shown in FIG. 4, the width d1 of the touch bonding area of the flexible printed circuit board FPCT for touch is 200 um), which will also affect the width of the glass frame of the circular panel.

(2) As shown in FIG. 2, in the on-cell touch display panel 1B, the touch sensor TS disposed on the encapsulation layer ENC is coupled to the flexible printed circuit board FPCT for touch and the flexible printed circuit board FPCT for touch is disposed on the COF layer on the opposite side of the TDDI integrated circuit, so that the flexible printed circuit board FPCT for touch needs to be coupled to the main flexible printed circuit board FPCM through a connector, leading to increased costs. In addition, as shown in FIG. 3, the traces of the touch sensor TS need to pass through the flexible printed circuit board FPCT, the main flexible printed circuit board FPCM and the chip-on-chip COF in order to be coupled to the TDDI integrated circuit makes the trace length too long, which is likely to cause signal attenuation and noise interference, which needs to be overcome urgently.

Therefore, the above-mentioned problems encountered by the prior art need to be further solved.

### SUMMARY OF THE INVENTION

Therefore, the invention provides a touch display apparatus to solve the above-mentioned problems occurred in the prior arts.

An embodiment of the invention is a touch display apparatus. In this embodiment, the touch display apparatus includes a touch display panel, a chip on film (COF) layer and a driving circuit. The touch display panel includes a display module and a touch sensor. The touch sensor is disposed on the display module. The COF layer includes a connecting portion and an extending portion connected to each other. The connecting portion is coupled to the display module and the extending portion is coupled to the touch sensor. The driving circuit is disposed on the COF layer. The driving circuit transmits touch signals with the touch sensor through the COF layer and its extending portion.

In an embodiment, the touch display panel is an on-cell touch display panel.

In an embodiment, the touch sensor is suitable for mutual-capacitance touch sensing or self-capacitance touch sensing.

In an embodiment, the display module includes an organic light-emitting diode (OLED) layer.

In an embodiment, the driving circuit is a touch and display driver integration (TDDI) integrated circuit.

In an embodiment, the driving circuit transmits display signals with the display module through the connecting portion of the COF layer.

In an embodiment, a shape of the touch display panel is circular, oval or arcuate.

In an embodiment, a width of the extending portion is smaller than a width of the connecting portion.

In an embodiment, the extending portion extends to the touch sensor from a center of the connecting portion.

In an embodiment, the extending portion extends to the touch sensor from a side of the connecting portion.

In an embodiment, at least one touch trace of the touch sensor passes through the extending portion and the COF layer in order and then coupled to the driving circuit.

In an embodiment, at least one display trace of the display module passes through the connecting portion and the COF layer in order and then coupled to a main flexible printed circuit board.

In an embodiment, at least one display trace of the display module passes through the connecting portion, the COF layer and the driving circuit in order and then coupled to a main flexible printed circuit board.

In an embodiment, the width of the extending portion is 18˜20 um.

In an embodiment, the extending portion includes a touch sensing pin for coupling to the touch sensor.

Compared to the prior arts, in the touch display apparatus according to the invention, the COF layer disposed with the TDDI integrated circuit is to extend its touch trace area to be coupled to the touch sensor of the on-cell touch display panel to replace the conventional FPC coupled to the touch sensor of the on-cell touch display panel, which not only reduces the cost and improves the bonding yield, but also the distance is short for the touch trace from the touch sensor through the COF layer to the TDDI integrated circuit, so that the signal attenuation is small and it is not susceptible to noise interference. In addition, due to the width of the bonding area between the COF layer and the touch sensor is only 18-20 um, which is much smaller than the width (200 um) of the conventional bonding area between the FPC and the touch sensor, which is, so it can also effectively reduce the influence of the glass frame width of the circular panel.

The advantage and spirit of the invention may be understood by the following detailed descriptions together with the appended drawings.

### BRIEF DESCRIPTION OF THE APPENDED DRAWINGS

FIG. 1 illustrates a schematic diagram of a flexible printed circuit board (FPC) for touch and a touch and display driver integration (TDDI) integrated circuit using a chip on film (COF) package coupled on the same side in the prior art.

FIG. 2 illustrates a schematic diagram of a FPC for touch and a TDDI integrated circuit using a COF package coupled on different sides in the prior art.

FIG. 3 illustrates a schematic diagram of the traces of the touch sensor passing through the FPC for touch, the main FPC and the COF layer to be coupled to the TDDI integrated circuit in the prior art.

FIG. 4 illustrates a schematic diagram of the wider width of the touch bonding area (for example, d1 is 200 um) required for the FPC for touch affecting the width of the glass frame of the circular pane in the prior art.

FIG. 5 illustrates a schematic diagram of the extending portion P2 of the COF layer coupled to the touch sensor TS according to a preferred embodiment of the invention.

FIG. 6 and FIG. 7 illustrate different embodiments of the extension portion P2 of the COF layer extending from the center and sides of the connecting portion P1 toward the touch sensor TS respectively.

FIG. 8 illustrates a schematic diagram of one terminal of the COF layer coupled to the touch sensor TS through the extending portion P2 and the other terminal of the COF layer coupled to the main flexible printed circuit board FPCM according to another preferred embodiment of the invention.

FIG. 9 illustrates a schematic diagram of the thinner width of the extending portion (for example, d2 is 18˜20 um) required for the COF layer without affecting the width of the glass frame of the circular panel in another preferred embodiment of the invention.

FIG. 10A illustrates a schematic diagram of the connecting portion P1 and the extending portion P2 of the COF layer located on the left and right sides respectively and the extending portion P2 located on the center being coupled to the driving circuit TDDI through the touch traces TR1˜TR2.

FIG. 10B illustrates a schematic diagram of the backside of the driving circuit TDDI in FIG. 10A.

FIG. 11A illustrates a schematic diagram of the connecting portion P1 of the COF layer located on the left and right sides and the extending portion P2 located on the center, and the extending portion P2 being coupled to the driving circuit TDDI through the touch traces TR1˜TR2.

FIG. 11B illustrates a schematic diagram of the backside of the driving circuit TDDI in FIG. 11A.

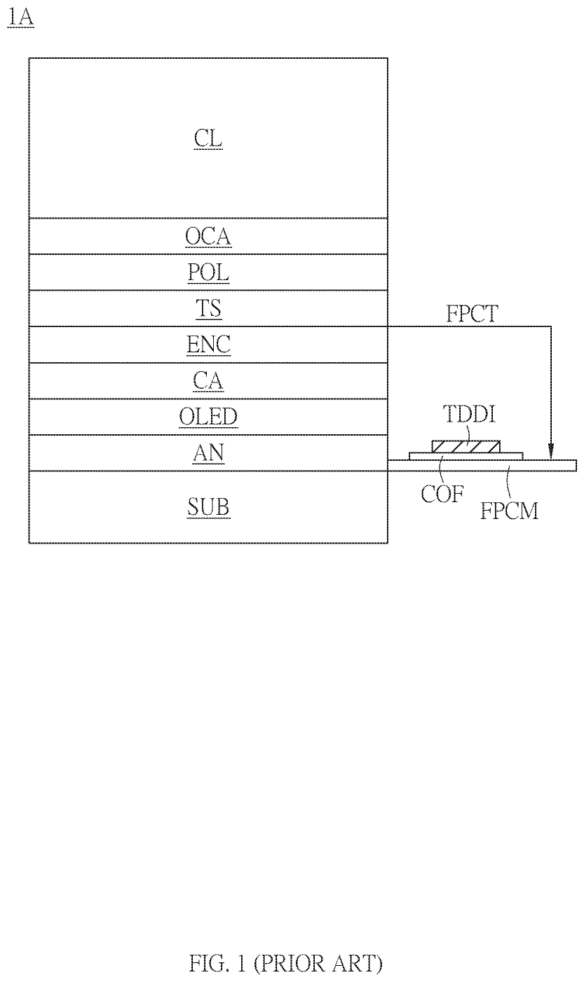

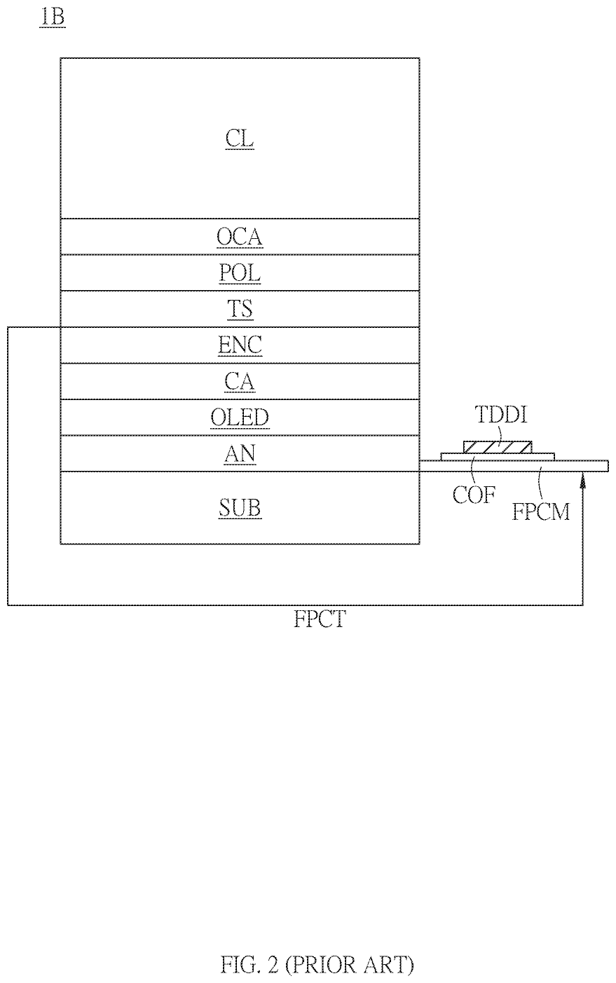

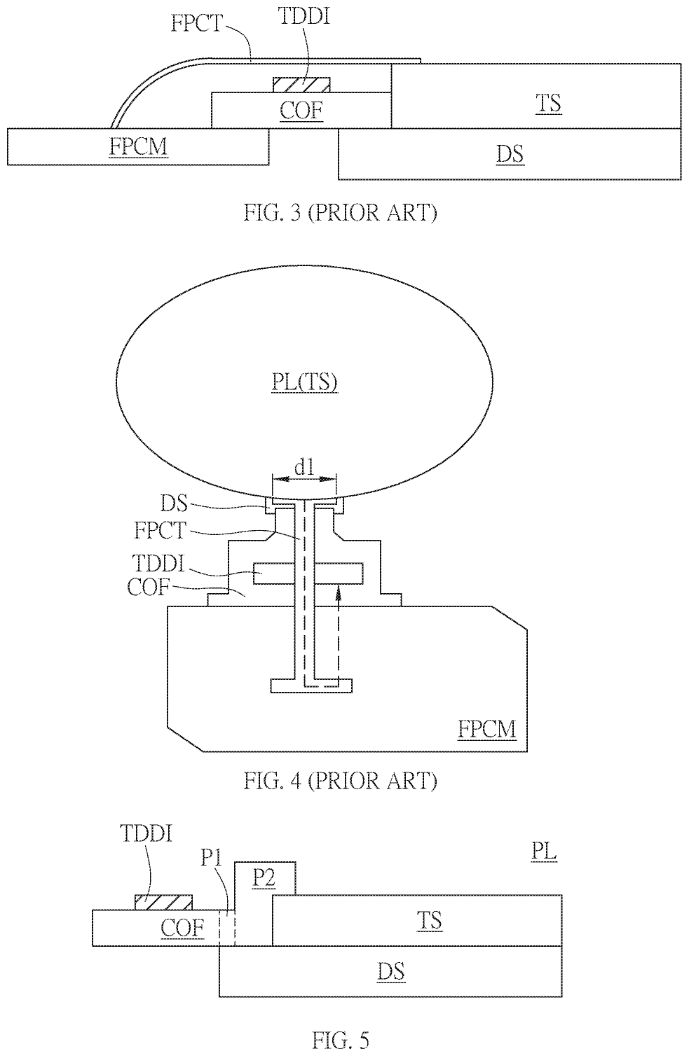

### DETAILED DESCRIPTION OF THE INVENTION

Reference will now be made in detail to the exemplary embodiments, the same or similar reference numbers or components used in the drawings and the embodiments are used to represent the same or similar parts.

A specific embodiment according to the invention is a touch display apparatus. In this embodiment, the touch display apparatus can be applied to a wearable apparatus, which can include an organic light-emitting diode (OLED) panel with an on-cell touch sensing architecture and an integrated touch and display driver (TDDI) integrated circuit, and can be applied to different touch sensing technologies, such as mutual-capacitance touch sensing and self-capacitance touch sensing, but not limited to this.

Please refer to FIG. 5. FIG. 5 illustrates a schematic diagram of the touch display apparatus in this embodiment.

As shown in FIG. 5, the touch display apparatus includes a touch display panel PL, a chip-on-film layer COF and a driving circuit TDDI. The touch display panel PL includes a display module DS and a touch sensor TS. The touch sensor TS is disposed on the display module DS. The driving circuit TDDI is disposed on the chip-on-film layer COF; that is to say, the driving circuit TDDI adopts the COF package structure.

The chip-on-film layer COF includes a connecting portion P1 and an extending portion P2 coupled to each other. The connecting portion P1 is coupled to the display module DS. The extending part P2 extends from the connecting portion P1 to the touch sensor TS and is coupled to the touch sensor TS. In this way, the driving circuit TDDI can be coupled to the touch sensor TS through the chip-on-film layer COF and its extending portion P2, so that the driving circuit TDDI can transmit touch signals with the touch sensor TS. Similarly, the driving circuit TDDI can also be coupled to the display module DS through the chip-on-film layer COF and its connecting portion P1, so that the driving circuit TDDI can transmit display signals with the display module DS.

In practical applications, the display module DS can include an OLED layer, a cathode layer and an anode layer; the driving circuit TDDI can be a TDDI integrated circuit; the extending portion P2 of the chip-on-film layer COF can include touch sensing pins for coupling to the touch sensor TS, but not limited to this.

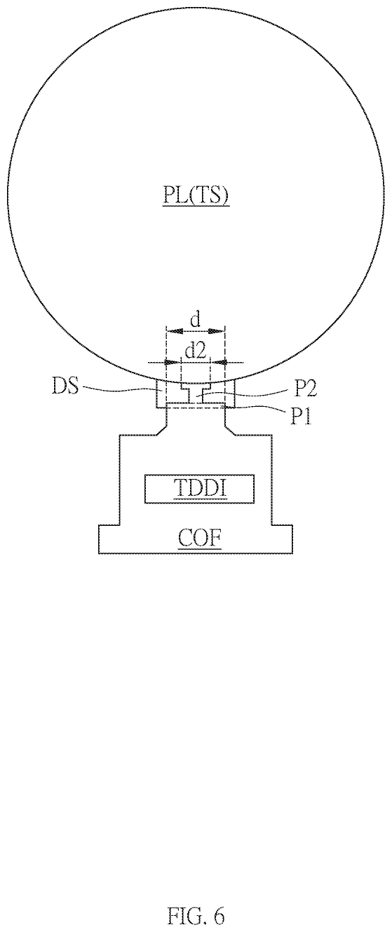

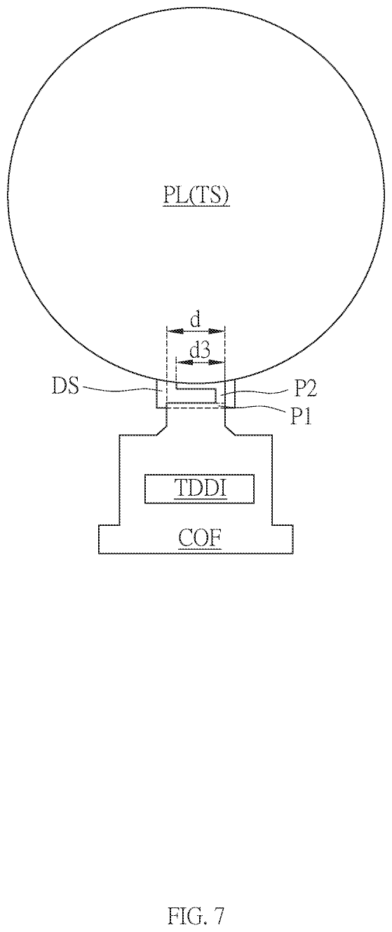

Next, please refer to FIG. 6 and FIG. 7. FIG. 6 and FIG. 7 illustrate different embodiments in which the extending portion P2 of the chip-on-film layer COF extends from the center and the sides of the connecting portion P1 toward the touch sensor TS respectively.

As shown in FIG. 6, the shape of the touch display panel PL is circular, the driving circuit TDDI is disposed on the chip-on-film layer COF, and the extending portion P2 of the chip-on-film layer COF extends from the center of the connecting part P1 toward the touch sensor TS of the touch display panel PL and is coupled to the touch sensor TS.

It should be noted that the connecting portion P1 and the extending portion P2 of the chip-on-film layer COF are coupled to the display module DS and the touch sensor TS of the touch display panel PL respectively, and the width d2 of the extending portion P2 in FIG. 6 will be smaller than the width d of the connecting portion P1.

Similarly, as shown in FIG. 7, the shape of the touch display panel PL is circular, the driving circuit TDDI is disposed on the COF, and the extending portion P2 of the chip-on-film layer COF extends from the side of the connecting part P1 toward the touch sensor TS of the touch display panel PL and is coupled to the touch sensor TS.

It should be noted that the connecting portion P1 and the extending portion P2 of the chip-on-film layer COF are coupled to the display module DS and the touch sensor TS of the touch display panel PL respectively, and the width d3 of the extending portion P2 in FIG. 7 will be smaller than the width d of the connecting portion P1.

In practical applications, the shape of the touch display panel PL can also be an ellipse, an arc or other shapes, and there is no specific limitation.

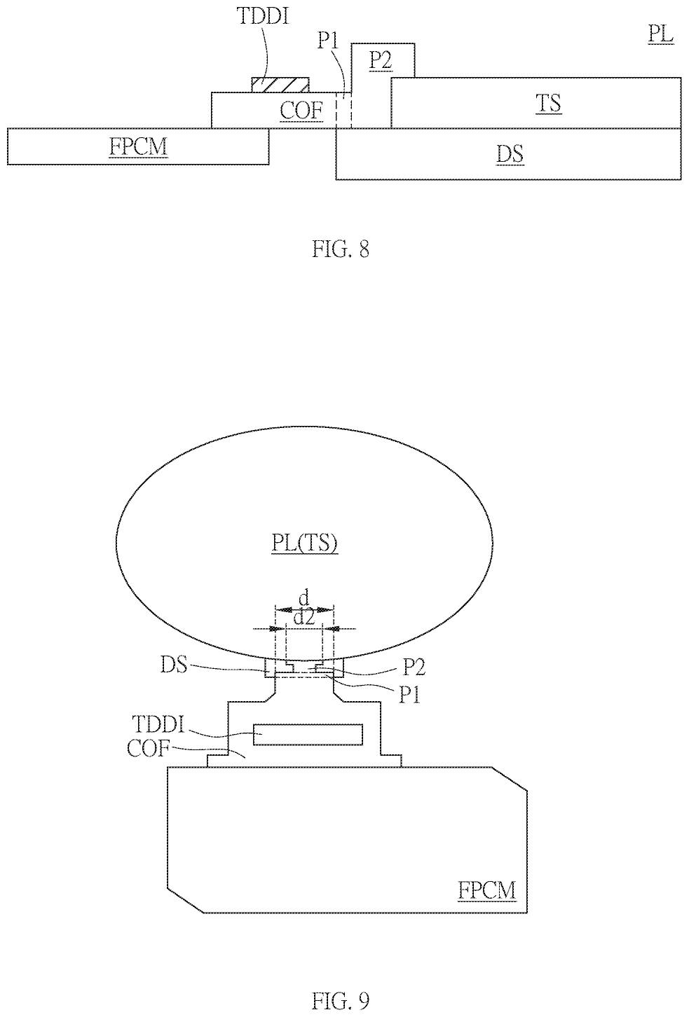

Please refer to FIG. 8. In another embodiment, one terminal of the chip-on-film layer COF is coupled to the touch sensor TS through the extending portion P2 and the other terminal of the chip-on-film layer COF is coupled to the main flexible printed circuit board FPCM. Therefore, in addition to the driving circuit TDDI can transmit touch signals to the touch sensor TS through the chip-on-film layer COF and its extending portion P2, the driving circuit TDDI can also transmit signals with the main flexible printed circuit board FPCM through the chip-on-film layer COF.

Please refer to FIG. 9. In another embodiment, the width d1 of the flexible printed circuit board FPCT for touch in the prior art is about 200 um (see FIG. 4), and the width d2 of the extending portion P2 of the chip-on-film layer COF is about 18˜20 um, which is obviously small, so it will not affect the glass frame width of the circular touch display panel PL.

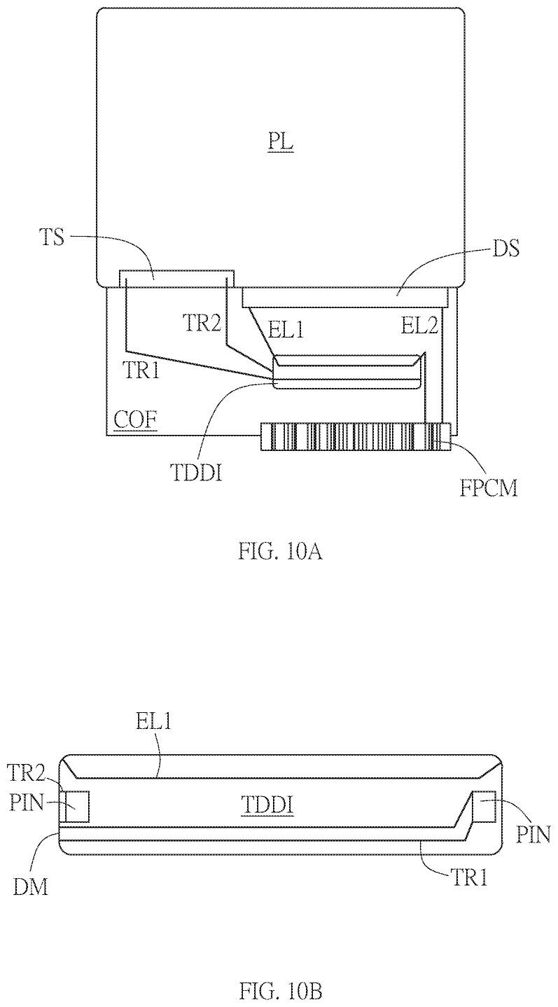

Please refer to FIG. 10A. In another embodiment, the touch sensor TS and the display module DS of the touch display panel PL are located on the left and right sides respectively. The touch traces TR1˜TR2 of the touch sensor TS are coupled to the driving circuit TDDI through the chip-on-film layer COF. The display trace EL2 of the display module DS is coupled to the main flexible printed circuit board FPCM through the chip-on-film layer COF, while the display trace EL1 is coupled to the main flexible printed circuit board FPCM through the chip-on-film layer COF and the driving circuit TDDI.

FIG. 10B illustrates a schematic diagram of the backside of the driving circuit TDDI in FIG. 10A. As shown in FIG. 10B, the display trace EL1 of the display module DS passes through the backside of the driving circuit TDDI, and the touch traces TR1˜TR2 of the touch sensor TS pass through the dummy pad DM on the backside of the driving circuit TDDI and coupled to the touch pins PIN located on both sides of the backside of the driving circuit TDDI to connect to the touch sensor TS.

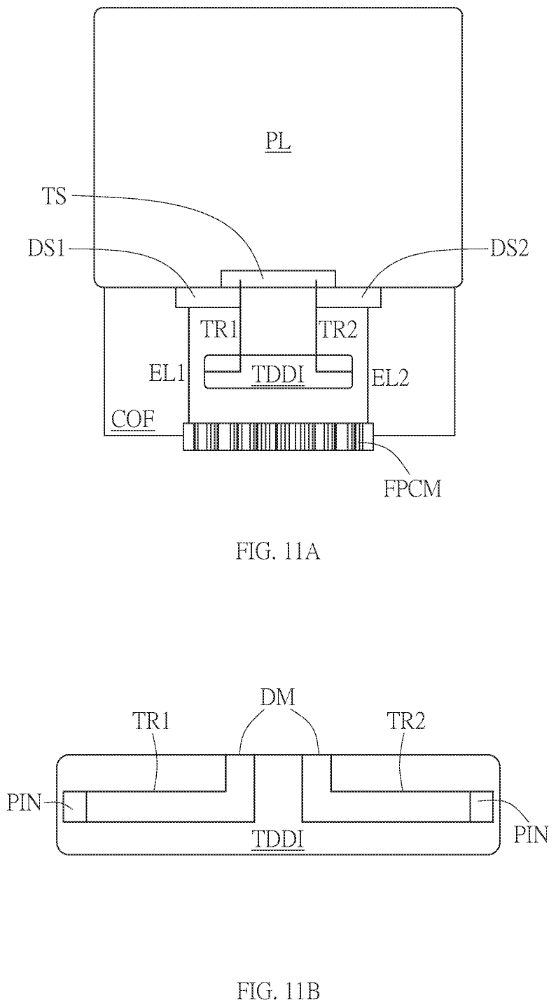

Please refer to FIG. 11A. In another embodiment, the display modules DS1˜DS2 of the touch display panel PL are located on the left and right sides, and the touch sensor TS is located on the center. The touch traces TR1˜TR2 of the touch sensor TS are coupled to the driving circuit TDDI through the chip-on-film layer COF. The display traces EL1˜EL2 of the display modules DS1˜DS2 are coupled to the main flexible printed circuit board FPCM through the chip-on-film layer COF.

FIG. 11B is a schematic diagram of the backside of the driving circuit TDDI in FIG. 11A. As shown in FIG. 11B, the touch traces TR1˜TR2 of the touch sensor TS are coupled to the touch pins PIN on both sides of the backside of the driving circuit TDDI through the dummy pads DM on the backside of the driving circuit TDDI to connect to the touch sensor TS.

Compared to the prior arts, in the touch display apparatus according to the invention, the COF layer disposed with the TDDI integrated circuit is to extend its touch trace area to be coupled to the touch sensor of the on-cell touch display panel to replace the conventional FPC coupled to the touch sensor of the on-cell touch display panel, which not only reduces the cost and improves the bonding yield, but also the distance is short for the touch trace from the touch sensor through the COF layer to the TDDI integrated circuit, so that the signal attenuation is small and it is not susceptible to noise interference. In addition, due to the width of the bonding area between the COF layer and the touch sensor is only 18-20 um, which is much smaller than the width (200 um) of the conventional bonding area between the FPC and the touch sensor, which is, so it can also effectively reduce the influence of the glass frame width of the circular panel.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A touch display apparatus, comprising:
a touch display panel, comprising:
a display module; and
a touch sensor, disposed on the display module;
a chip-on-film (COF) layer, comprising a connecting portion and an extending portion connected to each other, wherein the connecting portion is coupled to the display module and the extending portion is coupled to the touch sensor; and
a driving circuit, disposed on the COF layer;
wherein the driving circuit transmits touch signals with the touch sensor through the COF layer and the extending portion.

2. The touch display apparatus of claim 1, wherein the touch display panel is an on-cell touch display panel.

3. The touch display apparatus of claim 1, wherein the touch sensor is suitable for mutual-capacitance touch sensing or self-capacitance touch sensing.

4. The touch display apparatus of claim 1, wherein the display module comprises an organic light-emitting diode (OLED) layer.

5. The touch display apparatus of claim 1, wherein the driving circuit is a touch and display driver integration (TDDI) integrated circuit.

6. The touch display apparatus of claim 1, wherein the driving circuit transmits display signals with the display module through the connecting portion of the COF layer.

7. The touch display apparatus of claim 1, wherein a shape of the touch display panel is circular, oval or arcuate.

8. The touch display apparatus of claim 1, wherein a width of the extending portion is smaller than a width of the connecting portion.

9. The touch display apparatus of claim 1, wherein the extending portion extends to the touch sensor from a center of the connecting portion.

10. The touch display apparatus of claim 1, wherein the extending portion extends to the touch sensor from a side of the connecting portion.

11. The touch display apparatus of claim 1, wherein at least one touch trace of the touch sensor passes through the extending portion and the COF layer in order and then coupled to the driving circuit.

12. The touch display apparatus of claim 1, wherein at least one display trace of the display module passes through the connecting portion and the COF layer in order and then coupled to a main flexible printed circuit board.

13. The touch display apparatus of claim 1, wherein at least one display trace of the display module passes through the connecting portion, the COF layer and the driving circuit in order and then coupled to a main flexible printed circuit board.

14. The touch display apparatus of claim 1, wherein the width of the extending portion is 18˜20 um.

15. The touch display apparatus of claim 1, wherein the extending portion comprises a touch sensing pin for coupling to the touch sensor.
